(19) United States
(12) Patent Application Publication
(10) Pub. No.: US 2024/0414969 A1
(43) Pub. Date: Dec. 12, 2024

(54) Light-Emitting Device and Its Preparation Method, Electronic Device Having the Same

(71) Applicant: Najing Technology Corporation Limited, Hangzhou, Zhejiang (CN)

(72) Inventors: Yuan GAO, Hangzhou, Zhejiang (CN); Junjun PENG, Hangzhou, Zhejiang (CN)

(21) Appl. No.: 18/717,981

(22) PCT Filed: Dec. 7, 2022
(86) PCT No.: PCT/CN2022/137304

§ 371 Date: Jun. 7, 2024

(30) Foreign Application Priority Data
Dec. 8, 2021 (CN) 202111492040.9

(51) Int. Cl. H10K 59/32; H10K 59/12; H10K 59/122

(52) U.S. Cl. CPC H10K 59/32; H10K 59/1201; H10K 59/122

(57) ABSTRACT

The disclosure provides a light-emitting device, a method of preparing the light-emitting device and an electronic device. The light-emitting device includes a plurality of first electrodes disposed above the substrate; a stack of functional layers disposed above the plurality of first electrodes, the stack including at least a light-emitting layer, the light-emitting layer including a plurality of units, the plurality of units being disposed in correspondence with corresponding first electrodes of the plurality of first electrodes, and adjacent units of the plurality of units being in contact with each other; and a second electrode, disposed above the stack.

### CROSS-REFERENCE TO RELATED APPLICATION

This application claims priority to Chinese Patent Application No. 202111492040.9 filed to the China National Intellectual Property Administration on Dec. 8, 2021 and entitled “Light-emitting device and its preparation method, electronic device having the same”, the disclosure of which is hereby incorporated by reference in its entirety.

### TECHNICAL FIELD

The disclosure relates to the field of optoelectronic device, and more specifically, to a light-emitting device and a preparation method thereof, and an electronic device having the light-emitting device.

### BACKGROUND

Light-emitting devices such as light-emitting diodes are widely used in the fields of illumination and display. In a display device, a pixel definition layer (PDL) is usually provided for defining pixels. Typically, the pixel definition layer is presented in the form of a barrier structure (bank) to define the pixels for sub-pixels and thereby separate the pixels (or sub-pixels). The pixel definition layer is generally fabricated on a substrate of an active device, such as a thin film transistor (TFT), which is also referred to as a TFT substrate.

### SUMMARY

According to an aspect of the disclosure, there is provided a light-emitting device including a substrate; a plurality of first electrodes disposed above the substrate; a stack of functional layers disposed above the plurality of first electrodes, the stack including at least a light-emitting layer, the light-emitting layer including a plurality of units, the plurality of units being disposed in correspondence with corresponding first electrodes of the plurality of first electrodes, and adjacent units of the plurality of units being in contact with each other; and a second electrode, disposed above the stack.

In some embodiments, an orthographic projection of each of the plurality of units on the substrate covers an orthographic projection of the first electrode of the plurality of first electrodes corresponding to the unit on the substrate.

In some embodiments, the stack further includes a lower functional layer disposed below the light-emitting layer, the lower functional layer covering the plurality of first electrodes, and wherein the adjacent units of the plurality of units are in contact with each other such that the lower functional layer is not in contact with the second electrode.

In some embodiments, the stack further includes an upper functional layer disposed above the light-emitting layer, the upper functional layer covering the plurality of units of the light-emitting layer, and wherein the adjacent units of the plurality of units are in contact with each other such that the upper functional layer is not in contact with the lower functional layer.

In some embodiments, the plurality of units includes a first unit and a second unit, the first unit and the second unit being adjacent and partially overlapping each other.

In some embodiments, an orthographic projection of an overlapping region of the first unit and the second unit on the substrate does not overlap orthographic projections of the first electrodes of the first unit and the second unit on the substrate.

In some embodiments, the first unit is configured to emit light in a first wavelength range and the second unit is configured to emit light in a second wavelength range, the second wavelength range being higher than the first wavelength range.

In some embodiments, in the overlapping region of the first unit and the second unit, the second unit is closer to either the first electrode or the second electrode which acts as the light output side compared to the first unit.

In some embodiments, a hole transport energy level of the light-emitting material of the first unit is deeper than a hole transport energy level of the light-emitting material of the second unit, and an electron transport energy level of the light-emitting material of the first unit is not shallower than an electron transport energy level of the light-emitting material of the second unit, wherein, in the overlapping region of the first unit and the second unit, the first unit is closer to either the first electrode or the second electrode which acts as a cathode compared to the second unit.

In some embodiments, an electron transport energy level of the light-emitting material of the first unit is shallower than an electron transport energy level of the light-emitting material of the second unit, and a hole transport energy level of the light-emitting material of the first unit is not deeper than a hole transport energy level of the light-emitting material of the second unit, wherein, in the overlapping region of the first unit and the second unit, the second unit is closer to either the first electrode or the second electrode which acts as a cathode compared to the first unit.

In some embodiments, the electron transport energy level of the light-emitting material of the first unit is shallower than the electron transport energy level of the light-emitting material of the second unit, and the hole transport energy level of the light-emitting material of the first unit is deeper than the hole transport energy level of the light-emitting material of the second unit, wherein, in the overlapping region of the first and the second unit, the second unit is closer to either the first electrode or the second electrode which acts as a cathode compared to the first unit, or the first unit is closer to either the first electrode or the second electrode which acts as a cathode compared to the second unit.

In some embodiments, the plurality of units includes a third unit and a fourth unit that are adjacent to each other, the third unit and the fourth unit being configured to emit light of the same wavelength range, wherein the third unit and the fourth unit are integrally formed.

In some embodiments, the plurality of units of the light-emitting layer are formed by crosslinking of a printed or coated quantum dot composition.

In some embodiments, no isolation structure is provided between the plurality of units that extends from the substrate or the first electrode to a height of or above the plurality of units thereby separating the plurality of units.

In some embodiments, the light-emitting device further includes a plurality of isolation structures on the substrate that extend upwards from either the substrate or the first electrode, at least a portion of each first electrode of the plurality of first electrodes being provided between corresponding isolation structures, wherein each isolation structure of the plurality of isolation structures has a height of less than 700 nm.

In some embodiments, the height of each isolation structure of the plurality of isolation structures is configured to be within a range that is no higher than the sum of the height of the stack and 200 nm, and no lower than the height of the functional layer directly adjacent to the first electrode in the stack directly adjacent to the isolation structure.

According to another aspect of the disclosure, there is provided a method of preparing a light-emitting device including: providing a substrate having a plurality of first electrodes thereon; forming a stack of functional layers on the substrate, the stack including at least a light-emitting layer, the light-emitting layer including a plurality of units, the plurality of units being disposed in correspondence with corresponding first electrodes of the plurality of first electrodes, and adjacent units of the plurality of units are in contact with each other; and forming a second electrode on the stack.

In some embodiments, an orthographic projection of each of the plurality of units on the substrate covers an orthographic projection of the first electrode of the plurality of first electrodes corresponding to the unit on the substrate.

In same embodiments, forming the stack of functional layers further includes: forming a lower functional layer, the lower functional layer covering the plurality of first electrodes, wherein the light-emitting layer is disposed over the lower functional layer, and wherein adjacent units of the plurality of units of the light-emitting layer are in contact with each other such that the lower functional layer is not in contact with the second electrode formed on the stack.

In some embodiments, forming the stack of functional layers further includes: forming an upper functional layer, the upper functional layer covering the plurality of units of the light-emitting layer, wherein the light-emitting layer is disposed below the upper functional layer and adjacent units of the plurality of units of the light-emitting layer are in contact with each other such that the lower functional layer is not in contact with the upper functional layer formed on the light-emitting layer.

In some embodiments, forming the light-emitting layer includes: in correspondence with the plurality of first electrodes, forming liquid printing units corresponding to the plurality of units of the light-emitting layer, the liquid printing units including a quantum dot composition; and crosslinking the liquid printing units so as to form the plurality of units of the light-emitting layer.

In some embodiments, the plurality of units includes a first unit and a second unit, the first unit and the second unit being adjacent and partially overlapping each other.

In some embodiments, an orthographic projection of an overlapping region of the first unit and the second unit on the substrate does not overlap orthographic projections of the first electrodes of the first unit and the second unit on the substrate.

In some embodiments, the first unit is configured to emit light in a first wavelength range and the second unit is configured to emit light in a second wavelength range, the second wavelength range being higher than the first wavelength range.

In some embodiments, in the overlapping region of the first unit and the second unit, the second unit is closer to either the first electrode or the second electrode which acts as the light output side compared to the first unit.

In some embodiments, a hole transport energy level of the light-emitting material of the first unit is deeper than a hole transport energy level of the light-emitting material of the second unit, and an electron transport energy level of the light-emitting material of the first unit is not shallower than an electron transport energy level of the light-emitting material of the second unit, wherein, in the overlapping region of the first unit and the second unit, the first unit is closer to either the first electrode or the second electrode which acts as a cathode compared to the second unit.

In some embodiments, the electron transport energy level of the light-emitting material of the first unit is shallower than the electron transport energy level of the light-emitting material of the second unit, and the hole transport energy level of the light-emitting material of the first unit is not deeper than the hole transport energy level of the light-emitting material of the second unit, wherein, in the overlapping region of the first unit and the second unit, the second unit is closer to either the first electrode or the second electrode which acts as a cathode compared to the first unit.

In some embodiments, the electron transport energy level of the light-emitting material of the first unit is shallower than the electron transport energy level of the light-emitting material of the second unit, and the hole transport energy level of the light-emitting material of the first unit is deeper than the hole transport energy level of the light-emitting material of the second unit, wherein, in the overlapping region of the first and the second unit, the second unit is closer to one of the first electrode and the second electrode as a cathode, or the first unit is closer to either the first electrode or the second electrode which acts as a cathode compared to the first unit.

In some embodiments, the plurality of units includes a third unit and a fourth unit that are adjacent to each other, the third unit and the fourth unit being configured to emit light of the same wavelength range, wherein the third unit and the fourth unit are integrally formed.

According to yet another aspect of the disclosure, there is provided an electronic device including a light-emitting device according to any of the embodiments of the disclosure.

Other features of the disclosure and advantages thereof will become clearer through the following detailed description of exemplary embodiments of the disclosure with reference to the accompanying drawings.

### BRIEF DESCRIPTION OF THE DRAWINGS

The foregoing and other features and advantages of the disclosure will become clear from the following description of embodiments of the disclosure illustrated in conjunction with the accompanying drawings. The accompanying drawings, which are incorporated herein and form part of the specification, are further used to explain the principles of the disclosure and to enable those skilled in the art to make and use the disclosure. Among them:

FIGS. 1A and 1B illustrate a schematic diagram of the prior art using inkjet printing method for preparing a light-emitting device.

FIG. 2A illustrates a schematic diagram of a light-emitting device according to some embodiments of the disclosure.

FIG. 2B illustrates the microscopic photograph of quantum dot (QD) layer printed in an example light-emitting device having the structure shown in FIG. 2A, while FIG. 2C illustrates scan result of the step profiler corresponding to the region shown in FIG. 2B.

FIG. 3A illustrates a schematic diagram of a light-emitting device according to some embodiments of the disclosure.

FIG. 3B illustrates a microscopic photograph of a QD layer printed on layer in an example light-emitting device having the structure shown in FIG. 3A, while FIG. 3C illustrates the scan result of a step profiler corresponding to the region shown in FIG. 3B.

FIGS. 4A to 4C illustrate a light-emitting device according to yet other embodiments of the disclosure.

FIG. 5 illustrates the relationship of adjacent unit of the light-emitting layer and the bottom electrodes in the light-emitting device of FIG. 4B.

FIG. 6 illustrates a flow chart of a method of preparing a light-emitting device according to some embodiments of the disclosure.

FIGS. 7A to 7F illustrate preparation process example of light-emitting devices according to some embodiments of the disclosure.

FIGS. 8A to 10B illustrate electroluminescence spectra of QD light-emitting devices having different QD light-emitting layer overlapping modes.

Note that in the embodiments illustrated below, the same accompanying label is sometimes used in common between different accompanying drawings to denote the same portion or portions having the same function, and the repetition of their description is omitted. In some instances, similar labels and letters are used to denote similar items, so that once an item is defined in one of the accompanying drawings, no further discussion thereof is required in the subsequent accompanying drawings.

For ease of understanding, the location, dimension, and scope of each structure shown in the accompanying drawings, etc., do not represent the actual location, dimensions, and scope. Therefore, the disclosure is not limited to the location, dimension, scope, etc. disclosed in the accompanying drawings and the like.

### DETAILED DESCRIPTION OF THE EMBODIMENTS

Various exemplary embodiments of the disclosure will be described in detail below with reference to the accompanying drawings. It should be noted that the relative arrangements, numerical expressions, and values of the components and steps set forth in these embodiments do not limit the scope of the disclosure unless otherwise specifically stated.

The following description of at least one exemplary embodiment is in fact merely illustrative and in no way serves as any limitation on the disclosure and its application or use. That is, the structures and methods herein are shown in an exemplary manner to illustrate different embodiments of the structures and methods of the disclosure. However, those skilled in the art will understand that they are merely illustrative of exemplary ways in which the disclosure can be implemented and are not exhaustive. In addition, the accompanying drawings need not be drawn to scale, and some features may be enlarged to show details of specific components.

In addition, techniques, methods, and devices known to those of ordinary skill in the relevant field may not be discussed in detail, but where appropriate, the techniques, methods, and devices should be considered as part of specification of granted patent.

In all of the examples illustrated and discussed herein, any specific values should be interpreted as merely exemplary and not as limitations. Thus, other examples of exemplary embodiments may have different values.

In prior art, for the light-emitting device (such as display device), it is generally accepted by the skilled person that it is necessary to define the pixels by an isolation structure (bank), because without such an isolation structure, it is easy to cause pixels of different colors to contact each other and interfere with each other. In order to achieve a good isolation effect, the height of the isolation structure is often set to be as high as several micrometers, which greatly exceeds the height of the stack of functional layers of the light-emitting device.

However, the inventors of the present application realize that, especially when the functional layer such as the light-emitting layer is prepared by the method of inkjet printing, the ink droplets are affected by capillary effect at the isolation structure, and after drying, they accumulate at the edges of the isolation structure, resulting in an uneven film, which results in a poor light-emitting performance of the prepared light-emitting device. When a plurality of functional layers are formed, this edge accumulation phenomenon accumulates layer by layer. Moreover, since the formulation of each layer needs to satisfy the principle of orthogonality, the selection of solvents is limited, and it is therefore very difficult to realize a uniform film that is flat and does not pile up under such conditions with every formulation of the layer. In addition, ink development is generally based on adjusting the formulation and annealing process based on an open system, but the formulation optimized in this way is not necessarily suitable for substrate with isolated structures. In addition, the total film thickness of the functional layer of the device is typically several hundred nanometers (e.g., 100 to 200 nm), and in the case of top-emitting light-emitting device, the top electrode have to be formed thinly (typically, several tens of nanometers, e.g., 20 nm, in order not to impede the emission of light, and isolation structure of up to a few micrometers would make the contact of such thin top electrode unstable, which would lead to the emergence of bad dot (non-emitting pixel) to appear.

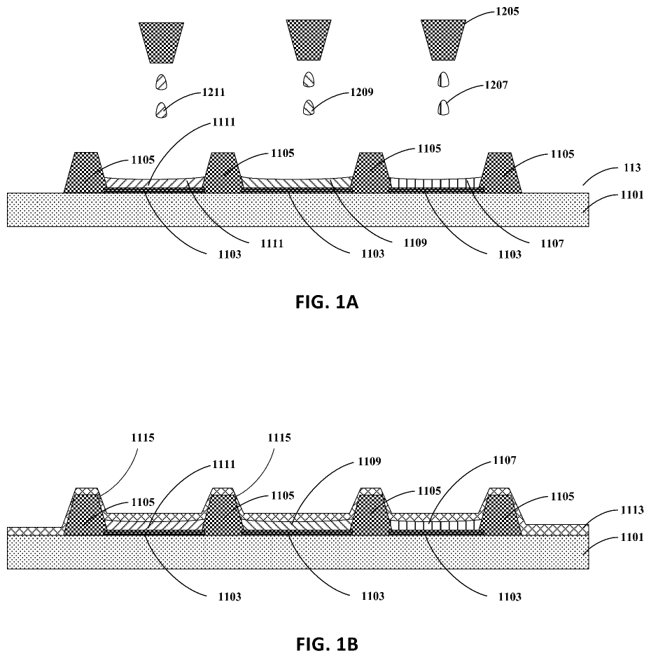

For example, FIGS. 1A and 1B illustrate a schematic diagram of an inkjet printing method for preparing a light-emitting device in the prior art. As shown in FIG. 1A, a plurality of bottom electrodes 1103 and a plurality of isolation structures 1105 for defining pixel region are formed on a substrate 1101. Ink droplets 1207, 1209, and 1211 containing a material for forming each functional layer are printed on the substrate 1101 via nozzle 1205, thereby printing the functional layers 1107, 1109, 1111 in the pixel regions defined by the isolation structures, such as a light-emitting layer, etc. It can be seen that the printed ink droplets 1207, 1209, 1211 are subject to a capillary effect at the isolation structure 1105 and will wet along the surface of the isolation structure 1105, resulting in a larger film thickness at the edge than at the center, thus making the material to form accumulation at the edges of the isolation structure 1105 after drying, causing the functional layers 1107, 1109, 1111 to be uneven. This phenomenon is more serious when forming a stack of functional layers (e.g., including a hole injection layer, a hole transport layer, a light-emitting layer, an electron transport layer, an electron injection layer etc.). As shown in FIG. 1B, a top electrode 1113 is typically employed to cover the entire tops of the functional layers 1107, 1109, 1111 and the isolation structures 1105. Since the height of the isolation structure differs significantly from the total thickness of the film, especially when the light-emitting device is configured as a top-emitting type resulting in a thin top electrode, it is easy to cause fracture of the top electrode (as shown by the crack 1115) which results in an unstable top electrode contact.

Accordingly, the inventors of the present application have acted counterintuitively by abandoning the design of the isolation structure in the prior art and provide a light-emitting device having a novel structure. The novel structure of such light-emitting device is counter-intuitive to a person skilled in the art, but the inventors of the present application has found through research that its light-emitting performance is not inferior to, or even significantly superior to, that of the light-emitting device having the isolation structure design of the prior art. Embodiments of the disclosure are specifically described below in conjunction with the accompanying drawings.

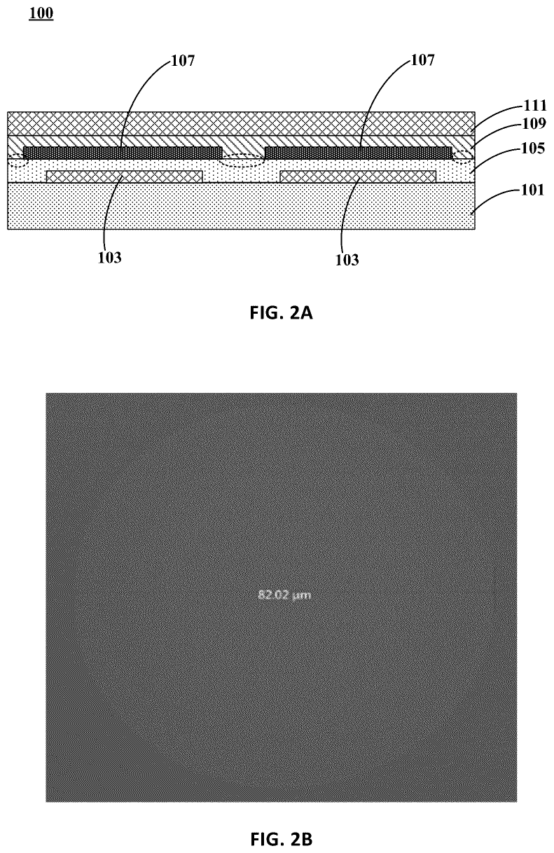

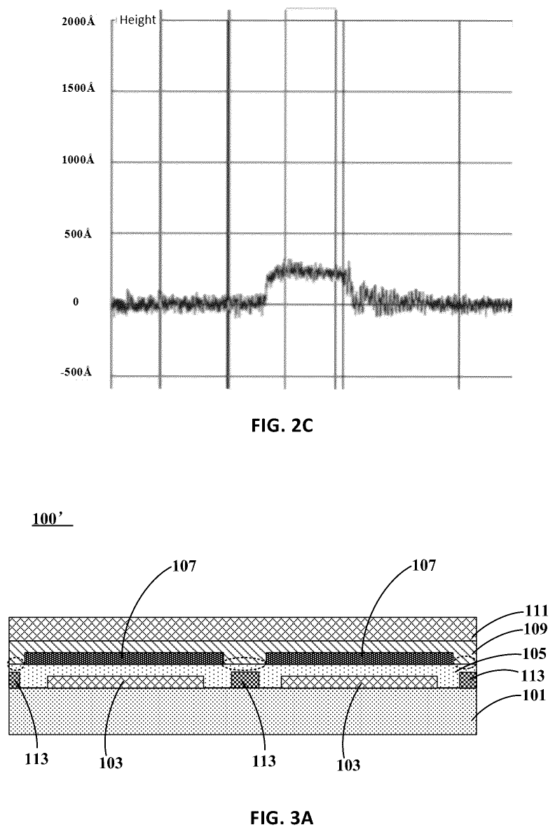

FIG. 2A illustrates a schematic diagram of a light-emitting device 100 according to some embodiments of the disclosure. As shown in FIG. 2A, the light-emitting device 100 includes a substrate 101, a plurality of first electrodes (also referred to as bottom electrodes) 103 are formed on the substrate 101. The light-emitting device 100 further includes a stack of functional layers (not labeled with accompanying labels) disposed on top of the plurality of first electrodes 103. The stack includes at least a light-emitting layer including a plurality of units 107 separated from each other disposed in correspondence with the corresponding first electrodes 103. The light-emitting device 100 further includes a second electrode (also referred to as a top electrode) disposed on top of the stack. Optionally, the stack further includes a lower functional layer 105 disposed underneath the light-emitting layer and/or an upper functional layer 109 disposed on top of the light-emitting layer. Herein, the functional layer has a general meaning in the art. As an exemplary description, the functional layer may mean a layer for the light-emitting unit, disposed between the top electrode and the bottom electrode of the light-emitting unit. The functional layer may include at least one of the following: a hole injection layer, a hole transport layer, a hole blocking layer, an electron injection layer, an electron transport layer, an electron blocking layer, a buffer layer, and/or any layer realizing other desired functions, and the like. In the embodiment shown in FIG. 2A, at least a portion of the upper functional layer 109 is disposed between adjacent units of the plurality of units 107 and at least a portion of the lower functional layer 105 is disposed between adjacent units of the plurality of units 107. In this embodiment, the plurality of units 107 are provided on the same layer. In other words, the plurality of units 107 are provided in the same layer with substantially the same thickness within a range of process accuracy.

In the light-emitting device 100 according to the present embodiment, no isolation structure extending upwardly from the substrate 101 or the first electrode 103 is provided between the plurality of units 107. In other words, in the light-emitting device of the embodiment of the disclosure, there is no pixel defining layer as in the prior art. Such design may be referred to herein as a no isolation structure design. This results in a uniform, flat film and top electrode in stable contact, which in turn results in improved light-emitting performance. For example, as shown in FIGS. 2B and 2C, in the quantum dot light-emitting device prepared according to the present embodiment, the formed QD film is substantially uniform from the edge to the middle, and the luminescence uniformity is good.

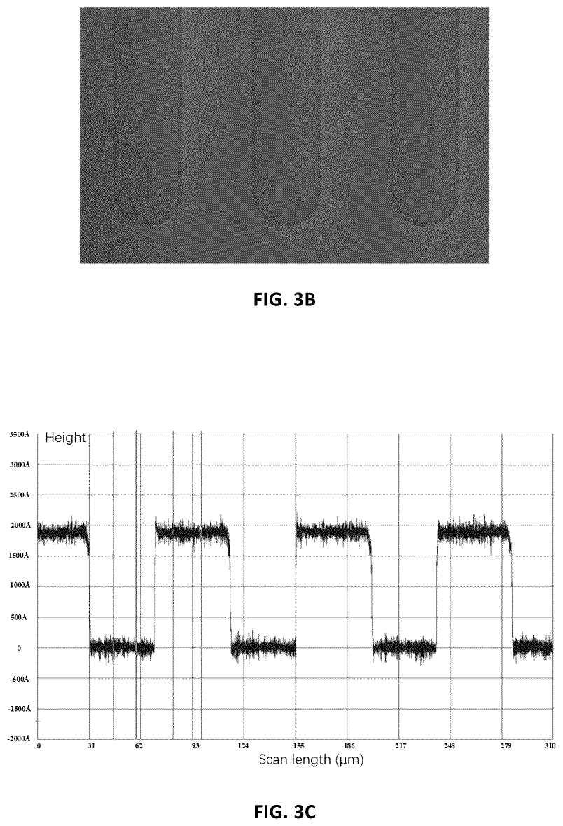

FIG. 3A illustrates a schematic diagram of a light-emitting device 100′. According to some other embodiments of the disclosure. The light-emitting device 100′ shown in FIG. 3A has substantially the same components as the light-emitting device 100 shown in FIG. 2A, for which the same components are denoted using the same accompanying label, and for which repetition of description is omitted. In contrast to the light-emitting device 100, the light-emitting device 100′ also includes a plurality of isolation structures 113, the isolation structures 113 may be used as pixel defining layers defining pixels. The isolation structures 113 are disposed on the substrate 101 and may extend upwardly from the substrate 101 or the first electrode 103. At least a portion of the first electrode 103 is provided between corresponding isolation structures 113. In some embodiments, such as shown in FIG. 3A, the first electrode 103 may be completely provided between the corresponding isolation structures 113. In some embodiments, a portion of the isolation structures 113 may overlap the first electrode 103. It should also be understood here that FIG. 3A shows a cross-sectional view of only a portion of the light-emitting device, and thus components such as its substrate 101 and isolation structure 113 may not be shown in their entirety. For example, when an unillustrated side of the isolation structure is not adjacent to the functional layer, there is no particular limitation on the unillustrated side. The isolation structures 113 may be formed from an inorganic or organic material. The inorganic material is for example, but not limited to, silicon nitride. The organic material may be, for example, a photoresist including a polyimide resin.

The height of the isolation structures 113 is relatively much smaller compared to isolation structures in conventional pixel defining layers. Such design may be referred to herein as a short isolation structure design. The inventors of the present application have found that such short isolation structure design can also achieve similar effects as the aforementioned non-isolation structure design, which can achieve a uniform, flat film as well as top electrode in stable contact, and thus improved light-emitting performance. Specifically, the inventors of the present application have found that by setting the height of the isolation structure to 700 nm or less, the unevenness of the film caused by the accumulation of the functional layer at the edges due to the capillary effect at the isolation structure can be reduced, and the uniformity of the film can thus be improved. In addition, by setting the height of the isolation structure to 700 nm or less, the uniformity of the film can be reduced. The reduced thickness difference between the stack of functional layers and the isolation structure allows for improved contact stability of the top electrode and reduced fracture. Preferably, the isolation structure 113 has a height of less than or equal to 500 nm, more preferably less than or equal to 400 nm, more preferably at 50-200 nm or 55-200 nm. When the height of the isolation structure is below 200 nm, the edges of the functional layers of the pixels can be made free of accumulation. Furthermore, when the height of the isolation structure is 200 nm or less, the problem of poor contact stability of the top electrode (when its thickness is thin) can be completely avoided. Preferably, the height of the isolation structure is not higher than the height of the stack of functional layers to be formed (i.e., the stack of all functional layers prior to the formation of the second electrode 111 (the top electrode) for the pixel or the light-emitting unit) by 200 nanometers, and is not lower than the height of the functional layer (e.g., for the case in which the first electrode 103 is configured to be the anode, which can be generally a hole injection layer directly adjacent to the first electrode 103 (the bottom electrode). Here, the height comparison is relative to the height of the first electrode 103 (bottom electrode). Here, the comparison of heights is relative to a common reference and, in general, to the surface of the substrate 101. Since the printed ink is often several micrometers thick when laid flat, the reduced isolation structure has less effect on the flow of the ink, thus reducing or eliminating accumulation at the edges of the functional layers and thus increasing the effective light-emitting area of the pixels.

As shown in FIGS. 3B and 3C, in the quantum dot light-emitting device prepared according to the present embodiment, the formed QD film is substantially uniform from the edge to the middle, and the uniformity of light emission is good.

In the art, in order to avoid light of different colors interfering with each other (i.e., not to have color-mixing problem), it is generally believed that a wider gap needs to exist between the units of the light-emitting layer (in particular, units configured to emit light of different wavelength ranges, which may also be referred to herein as different-color units). A person of ordinary skill, upon seeing that the novel light-emitting devices 100, 100′ presented in the disclosure eliminate or lower the isolation structure used to separate adjacent units of the light-emitting layer, would assume that a wider gap is needed between the different color units of the light-emitting layer than a regular case. However, the inventors of the present application realize that, as marked by the dotted lines in FIG. 2A and FIG. 3A, in such a gap region, since it is not completely obscured by the light-emitting layer, the lower functional layer 105, which is located under the light-emitting layer, is in direct contact with the upper functional layer 109, which can cause serious electrical leakage problem, resulting in low luminous efficiency and high energy consumption of the light-emitting device.

To this end, the inventors of the present application again counter-intuitively provide yet another improved light-emitting device including: a substrate; a plurality of first electrodes disposed above the substrate; a stack of functional layers disposed above the plurality of first electrodes, the stack including at least a light-emitting layer, the light-emitting layer including a plurality of units, the plurality of units are provided in correspondence with corresponding first electrodes of the plurality of first electrodes, and adjacent units of the plurality of units are in contact with each other; and a second electrode, which is disposed above the stack. As a result, a continuous light-emitting layer can be realized by connecting the units in the light-emitting layer two by two by making the units in the light-emitting layer in direct contact with each other, thereby suppressing leakage without passing through the light-emitting layer caused by direct contact between the film disposed on top of the light-emitting layer and the film disposed below the light-emitting layer. Such a light-emitting device will be further described below in connection with the accompanying drawings.

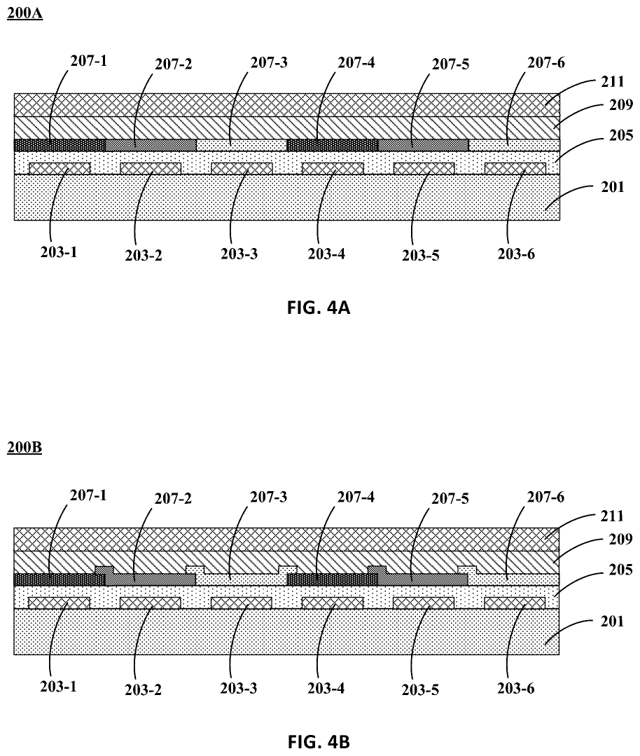

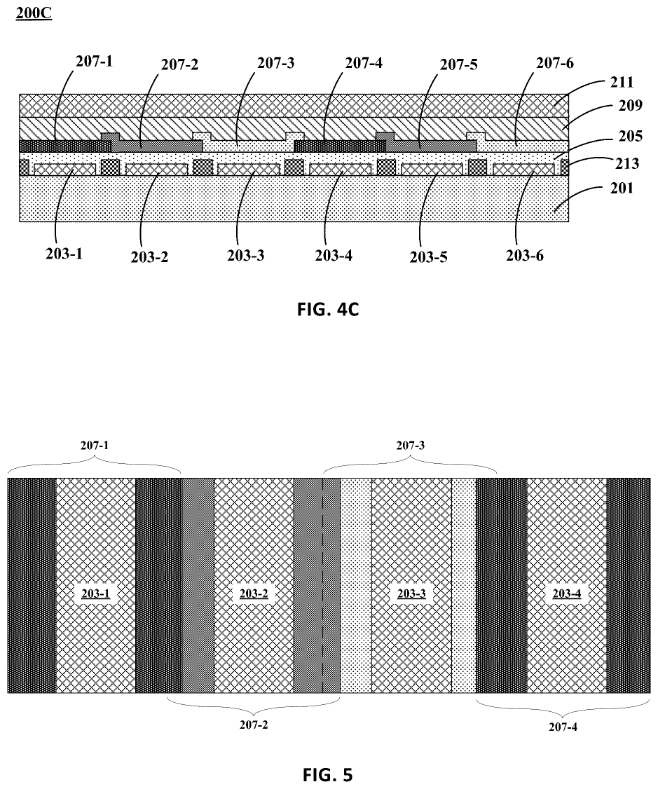

FIG. 4A illustrates a light-emitting device 200A according to some embodiments of the disclosure. The light-emitting device 200A includes a substrate 201 and a plurality of first electrodes 203-1 to 203-6 (which may be collectively referred to as the first electrodes 203) disposed on top of the substrate 201. The substrate 201 may be a light-transmissive or light-impermeable substrate, and may be a rigid or flexible substrate; the disclosure is not limited thereto. The light-emitting device 200A further includes a stack of functional layers (not shown with accompanying labels) disposed above the plurality of first electrodes. The stack includes at least a light-emitting layer including a plurality of units 207-1 to 207-4 (which may be collectively referred to as units 207) disposed in correspondence with corresponding first electrodes of the plurality of electrodes. In some embodiments, the units 207 may be provided in one-to-one correspondence with the first electrode 203. For example, unit 207-1 is provided in correspondence with first electrode 203-1, unit 207-2 is provided in correspondence with first electrode 203-2, unit 207-3 is provided in correspondence with first electrode 203-3, unit 207-4 is provided in correspondence with first electrode 203-4, unit 207-5 is provided in correspondence with first electrode 203-5, and unit 207-6 is provided in correspondence with first electrode 203-6. The light-emitting device 200A further includes a second electrode 211 disposed above the stack of functional layers. One of the first electrode 203 and the second electrode 211 may be configured as a cathode, and the other may be configured as an anode, and is not specifically limited herein. In some embodiments, the second electrode 211 may be a whole-surface electrode (or a blanket electrode) that may cover functional layers of a plurality of pixels. However, the disclosure is not limited thereto. In some embodiments, the second electrode 211 may be configured to allow light emitted by the light-emitting layer to be transmitted therefrom.

In particular, in the light-emitting device 200, adjacent units of the plurality of units of the light-emitting layer are in contact with each other. As shown in FIG. 4A, unit 207-1 is in contact with unit 207-2, unit 207-2 is in contact with unit 207-3, unit 207-3 is in contact with 207-4, unit 207-4 is in contact with 207-5, unit 207-5 is in contact with 207-6. In some embodiments, the stack may further include a lower functional layer 205 disposed below the light-emitting layer, the lower functional layer 205 covering the plurality of first electrodes 203, and wherein the plurality of adjacent units contact each other such that the lower functional layer 205 is not in contact with the second electrode 211. In some embodiments, the stack further includes an upper functional layer 209 disposed above the light-emitting layer, the upper functional layer 209 covering the plurality of units 207 of the light-emitting layer, and wherein adjacent units of the plurality of units are in contact with each other such that the upper functional layer 209 is not in contact with the lower functional layer 205. As a result, the leakage phenomenon of the light-emitting device 200 is effectively suppressed, thereby realizing an increase in the light-emitting efficiency and lifetime as well as a reduction in energy consumption.

Although the lower functional layer 205 and the upper functional layer 209 are shown as a single layer in FIG. 4A, they may be multiple layers. For example, when the first electrode 203 is configured as an anode and the second electrode 211 is configured as a cathode, the upper functional layer 209 may include one or more of an electron injection layer, an electron transport layer, and a hole blocking layer, and the lower functional layer 205 may include one or more of a hole transport layer, a hole injection layer, and an electron blocking layer. Also, although in the embodiment shown in FIG. 4A, the one or more functional layers are shown in whole form, that is, the functional layers may be used together for a plurality of pixels or sub-pixels, yet in other embodiments, the functional layers may also include a plurality of units, and a single unit may be used for one or more pixels or sub-pixels.

In some embodiments, to further improve the isolation between the upper functional layer 209 and the lower functional layer 205, adjacent units between the plurality of units 207 of the light-emitting layer may be made to partially overlap each other. As shown in FIG. 4B, units 207-1 and units 207-2 being adjacent to each other partially overlap each other, units 207-2 and units 207-3 partially overlap each other, units 207-3 and units 207-4 partially overlap each other, units 207-4 and units 207-5 partially overlap each other, and units 207-5 and units 207-6 partially overlap each other. In some examples, some or all of the adjacent units in the light-emitting layer may partially overlap each other. The degree of overlap between each pair of adjacent units need not necessarily be the same.

Also, in some embodiments, the orthographic projection of each unit 207 of the light-emitting layer on the substrate 201 may cover the orthographic projection of the first electrode 203 corresponding to the unit 207 on the substrate 201. In this way, the light-emitting efficiency can be improved. In some embodiments, two adjacent units 207 partially overlap each other, and the orthographic projection on the substrate 201 of the overlapping region of the two units 207 does not overlap the orthographic projection on the substrate 201 of the first electrode 203 corresponding to either of the two units 207. In this way, the light-emitting efficiency can be improved; it is also possible to reduce crosstalk when adjacent units are configured to emit light of different wavelength ranges. As shown in FIG. 5, the orthographic projection of the unit 207-1 on the substrate 201 covers the orthographic projection of the first electrode 203-1 on the substrate 201, the orthographic projection of the unit 207-2 on the substrate 201 covers the orthographic projection of the first electrode 203-2 on the substrate 201, the orthographic projection of the unit 207-3 on the substrate 201 covers the orthographic projection of the first electrode 203-3 on the substrate 201, the orthographic projection of the unit 207-4 on the substrate 201 covers the orthographic projection of the first electrode 203-4 on the substrate 201, the orthographic projection on the substrate 201 of the overlapping region of the unit 207-1 and the unit 207-2 does not overlap the orthographic projection on the substrate 201 of the first electrode 203-1 and the first electrode 203-2, the orthographic projection on the substrate 201 of the overlapping region of the unit 207-2 and the unit 207-3 does not overlap the orthographic projection on the substrate 201 of the first electrode 203-2 and the first electrode 203-3 on the substrate 201, and the orthographic projection of the overlapping region of unit 207-3 with unit 207-4 on the substrate 201 does not overlap with the orthographic projection of the first electrode 203-3 and the first electrode 203-4 on the substrate 201. It should be understood that while unit 207 and first electrode 203 are illustrated as an elongated strip in the example of FIG. 5, this is merely exemplary and not limiting, and the unit 207 and first electrode 203 of the disclosure may have any other suitable shape.

In some embodiments, the units of the light-emitting layer are formed by crosslinking the printed or coated quantum dot compositions, which may be thermal crosslinking or photo crosslinking. In this way, the quantum dot light-emitting device can be formed. In some embodiments, the quantum dots may be configured to be uniformly dispersed in ink droplets for inkjet printing.

In some embodiments, a portion of the lower functional layer 205 (or one or more of the layers) beneath the light-emitting layer may be treated so that its surface properties are different from the remainder, thereby exerting an effect on the printing of the ink droplets. For example, a portion of the surface of the lower functional layer 205 (or one or more of the layers) may be treated with UV light so as to change its hydrophilic or other properties. However, since the functional layer is usually a layer having requirements for optoelectronic properties or other properties or the like, and its composition is complex, such treatment may result in an unfavorable effect on the optoelectronic properties, the chemical properties, or the surface flatness or the like, thereby affecting the performance of the device. In addition, in the process of patterning by surface affinity treatment, it is required that the materials of each functional layer have the same surface affinity, which makes the selection of the materials of the functional layer more stringent, and at the same time, it is necessary to take into account the optoelectronic properties of the light-emitting device. Therefore, in a more preferred embodiment, instead of such a process, the surface properties of the various portions of the lower functional layer are made consistent. In this way, the process complexity is reduced, the preparation efficiency is improved, the cost is reduced, and the impact on the device performance is minimized.

Each of the plurality of units 207 of the light-emitting layer, the corresponding first electrode 203 and the corresponding portion of the second electrode 211 may be included in corresponding pixel. The corresponding first electrode 203, the corresponding portion of the stack of functional layers, and the corresponding portion of the second electrode 211 together form the light-emitting unit. Generally, the pixel may include one or more light-emitting units. The pixel may also include a plurality of sub-pixels, each sub-pixel having a light-emitting unit. For example, the pixel may include red, green, blue (RGB) three types of light-emitting units which can also be referred to as sub-pixel.

In different embodiments, the light-emitting device according to the disclosure may be a bottom-emitting light-emitting device that emits light through the first electrode and the substrate, a top-emitting light-emitting device that emits light through the second electrode, or a double-sided emitting light-emitting device that emits light through both.

As a result, the disclosure suppresses the leakage phenomenon of the light-emitting device by making the adjacent units of the light-emitting layer in contact with each other, and realizes improved light-emitting efficiency and reduced energy consumption. Further, with respect to the previously mentioned color mixing problem commonly feared in the art as occurring due to insufficient gap between different color units, the inventors of the present application have found that the occurrence of the color mixing problem can be well suppressed by reasonably setting the order of overlap between different color units of the light-emitting layer.

On the one hand, the inventors of the present application study the problem from the perspective of carriers. In the light-emitting device, a hole injected from an anode meets an electron injected from a cathode to undergo radiative recombination and thus emit light. When a light-emitting layer configured to emit light of a different wavelength range exists between the anode and the cathode, the light-emitting layer will emit light only if the electrons and holes are capable of radiative recombination in that light-emitting layer. The position of the recombination of electrons and holes depends on the energy level arrangement of the structure of each layer in the light-emitting device. Accordingly, it is assumed that the light-emitting layer includes first unit (e.g., a blue light unit) and a second unit (e.g., a red light unit) are adjacent to each other, that the first unit and the second unit partially overlap with each other, and that the first unit is configured to emit light in a first wavelength range, and that the second unit is configured to emit light in a second wavelength range, the second wavelength range being higher than the first wavelength range. It should be understood that while the discussion herein is exemplified by the first unit being the blue light unit and the second unit being the red light unit, this is merely exemplary and not limiting. For example, in the RGB light-emitting device, the green light unit may serve as the first unit and the red light unit may serve as the second unit for the neighboring red light unit and green light unit; the blue light unit may serve as the first unit and the red light unit may serve as the second unit for the neighboring red light unit and blue light unit; and the blue light unit may serve as the first unit and the green light unit may serve as the second unit for the neighboring blue light unit and green light unit. It is understood that for any two units that satisfies “the second wavelength range being higher than the first wavelength range”, they are applicable to the discussion here.

If the hole transport energy level of the light-emitting material of the first unit (e.g., a blue light unit) is deeper than the hole transport energy level of the light-emitting material of the second unit (e.g., a red light unit and the first unit (e.g., the blue light unit) of the light-emitting material has an electron transport energy level deeper than that of the light-emitting material of the second unit (e.g., the red light unit), then in the overlapping region of the first unit (e.g., the blue light unit) and the second unit (e.g., the red light unit), the first unit (e.g., the blue light unit) is closer to either the first electrode or the second electrode which acts as the cathode may be preferred. This is because, when the structure of the light-emitting device is “anode/ . . . /first unit/second unit/ . . . cathode”, electrons injected into the second unit from the cathode can be injected into the first unit from the second unit, and holes injected into the first unit from the anode can be injected into the second unit from the first unit, and thus both the first unit and the second unit can emit light (color mixing occurs), which is not desired. When the structure of the light-emitting device is “anode/ . . . /second unit/first unit/ . . . cathode”, electrons injected into the first unit cannot be injected into second unit due to the electronic potential barrier existing at the interface of the second unit and the first unit, holes injected into the second unit from the anode cannot be injected into the first unit from the second unit due to the hole potential barrier existing at the interface of the second unit and the first unit, neither the first unit nor the second unit can emit (no color mixing occurs). Therefore, in the case of the relative positional relationship between the hole transport energy level and the electron transport energy level of the first unit and the second unit described herein, if the first unit is arranged to be closer to either the first electrode or the second electrode which acts as the cathode compared to the second unit in the overlapping region of the first unit and the second unit, it is possible to cause both the first unit and the second unit not to emit light in the overlapping region, and so no color mixing problem; and visually the light-emitting regions of the first unit and the second unit do not appear to overlap.

If the hole transport energy level of the light-emitting material of the first unit (e.g., a blue light unit) is deeper than the hole transport energy level of the light-emitting material of the second unit (e.g., a red light unit), and the first unit (e.g., the blue light unit) of the light-emitting material has an electron transport energy level that is equal to the electron transport energy level of the light-emitting material of the second unit (e.g., the red light unit), then in the overlapping region of the first unit (e.g., the blue light unit) and the second unit (e.g., the red light unit), the first unit (e.g., the blue light unit) is closer to either the first electrode or the second electrode which acts as the cathode may be preferred. This is because, when the structure of the light-emitting device is “anode/ . . . /first unit/second unit/ . . . cathode”, electrons injected into the second unit from the cathode can be injected into the first unit from the second unit, and holes injected into the first unit from the anode can be injected into the second unit from the first unit, and thus both the first unit and the second unit can emit light (color mixing occurs), which is not desired. When the structure of the light-emitting device is “anode . . . /second unit/first unit/ . . . cathode”, electrons injected into the first unit from the cathode can be injected into the second unit from the first unit. However, holes injected into the second unit from the anode cannot be injected into the first unit from the second unit due to a hole barrier existing at the interface of the second unit and first unit, so that only the second unit emits light and the first unit does not emit light (no color mixing occurs). Therefore, in the case of the relative positional relationship between the hole transport energy level and the electron transport energy level of the first unit and the second unit described herein, if the first unit is arranged to be closer to either the first electrode or the second electrode which acts as a cathode compared to the second unit in the overlapping region of the first unit and the second unit, it can make only the second unit emit light in the overlapping region, and therefore the problem of mixing of colors does not occur.

If the hole transport energy level of the light-emitting material of the first unit (e.g., a blue light unit) is equal to the hole transport energy level of the light-emitting material of the second unit (e.g., a red light unit), and the first unit (e.g., the blue light unit) of the light-emitting material has an electron transport energy level shallower than that of the light-emitting material of the second unit (e.g., the red light unit), then in the overlapping region of the first unit (e.g., the blue light unit) and the second unit (e.g., the red light unit), the second unit (e.g., the red light unit) is closer to either the first electrode or the second electrode which acts as the cathode may be preferred. This is because, when the structure of the light-emitting device is “anode/ . . . /second unit/first unit/ . . . cathode”, electrons injected into the first unit from the cathode can be injected into the second unit from the first unit, and holes injected into the second unit from the anode can be injected into the first unit from the second unit, and so both the first unit and the second unit can emit light (color mixing occurs), which is not desired; when the structure of the light-emitting device for the “anode/ . . . /first unit/second unit/ . . . cathode”, the electrons injected from the cathode into the second unit cannot be injected from the second unit into the first unit due to the electronic potential barrier existing at the interface of the second unit and the first unit, but the holes injected from the anode into the first unit can be injected from the first unit into the second unit, and so only the second unit emits light while the first unit does not emit light (no color mixing). Therefore, in the case of the relative positional relationship between the hole transport energy level and the electron transport energy level of the first unit and the second unit described herein, if the second unit is arranged to be closer to either the first electrode or the second electrode which acts as the cathode compared to the first unit in the overlapping region of the first unit and the second unit, it can make only the second unit emit light in that overlapping region, and thus no color mixing problem occurs.

If the hole transport energy level of the light-emitting material of the first unit (e.g., a blue light unit) is shallower than the hole transport energy level of the light-emitting material of the second unit (e.g., a red light unit), and the first unit (e.g., the blue light unit) of the light-emitting material has an electron transport energy level shallower than that of the light-emitting material of the second unit (e.g., the red light unit), then in the overlapping region of the first unit (e.g., the blue light unit) and the second unit (e.g., the red light unit), the second unit (e.g., the red light unit) is closer to either the first electrode or the second electrode which acts as the cathode may be preferred. This is because, when the structure of the light-emitting device is “anode/ . . . /second unit/first unit/ . . . cathode”, electrons injected into the first unit from the cathode can be injected into the second unit from the first unit, and holes injected into the second unit from the anode can be injected into the first unit from the second unit, and so both the first unit and the second unit can emit light (color mixing occurs), which is not desired. When the structure of the light-emitting device is “anode/ . . . /first unit/second unit/ . . . cathode”, electrons injected from the cathode into the second unit cannot be injected from the second unit into the first unit due to the electron potential barrier existing at the interface of the second unit and first unit, and holes injected from the anode into the first unit cannot be injected from the first unit into the second unit due to the hole potential barrier existing at the interface of the first unit/second unit, both the first unit and the second unit cannot emit light (no mixing of colors occurs). Therefore, in the case of the relative positional relationship between the hole transport energy level and the electron transport energy level of the first unit and the second unit described herein, if the second unit is arranged to be closer to either the first electrode or the second electrode which acts as the cathode compared to the first unit in the overlapping region of the first unit and the second unit, it can make both the first unit and the second unit not emit light in the overlapping region, and therefore no color-mixing problem will occur; and visually the light-emitting regions of the first unit and the second unit do not appear to overlap.

If the hole transport energy level of the light-emitting material of the first unit (e.g., a blue light unit) is deeper than the hole transport energy level of the light-emitting material of the second unit (e.g., a red light unit), and the first unit (e.g., the blue light unit) of the light-emitting material has an electron transport energy level that is shallower than that of the light-emitting material of the second unit (e.g., the red light unit), then in the overlapping region of the first unit (e.g., the blue light unit) and the second unit (e.g., a red light unit), it is feasible that the second unit (e.g., the red light unit) being closer to either the first electrode or the second electrode which acts as the cathode compared to the first unit (e.g., the blue light unit), or the first unit (e.g., the blue light unit) being closer to either the first electrode or the second electrode as the cathode compared to the second unit (e.g., the red light unit). This is because, when the structure of the light-emitting device is “anode/ . . . /second unit/first unit/ . . . cathode”, electrons injected into the first unit from the cathode can be injected into the second unit from the first unit, but holes injected into the second unit from the anode cannot be injected into the first unit from the second unit due to a hole barrier existing at the interface of the second unit and first unit. So only the second unit emits light and the first unit does not emit light (no color mixing occurs). When the structure of the light-emitting device is “anode/ . . . /first unit/second unit/ . . . cathode”, the electrons injected into the second unit from the cathode cannot be injected into the first unit from the second unit due to the electronic barrier at the interface of the second unit and the first unit, but the holes injected into the first unit from the anode can be injected into the second unit from the first unit, so that only the second unit emits light and the first unit does not emit light (no color mixing occurs). Therefore, in the case of the relative positional relationship between the hole transporting energy level and the electron transporting energy level of the first unit and the second unit described herein, in the overlapping region of the first unit and the second unit, whether the second unit is arranged to be closer to either the first electrode or the second electrode which acts as a cathode compared to the first unit or the first unit is arranged to be closer to either the first electrode or the second electrode which acts as the cathode as compared to the second unit, both solutions can make the first unit and the second unit not emit light in the overlapping region, so that the problem of color mixing does not occur.

For purposes herein, depending on the particular material, “hole transport energy level” may refer to the highest occupied molecular orbital (HOMO) energy level and “electron transport energy level” may refer to the lowest unoccupied molecular orbital (LUMO) energy level; or “hole transport energy level” may refer to a valence band energy level and “electron transport energy level” may refer to a conduction band energy level; the disclosure is not limited thereto.

In another aspect, the inventors of the present application study this problem from a photonic perspective. In the light-emitting device, the band gap of the light-emitting material of the second unit (e.g., the red light unit) is narrower than the band gap of the light-emitting material of the first unit (e.g., the blue light unit), because the second wavelength range of the second unit (e.g., the red light unit) is higher than the first wavelength range of the first unit (e.g., the blue light unit). Accordingly, in the overlapping region of the first unit and the second unit, arranging the second unit (e.g., the red light unit) to be closer to either the first electrode or the second electrode which acts as the light output side as compared to the first unit (e.g., the blue light unit), is also effective in suppressing the color mixing problem. This is because, when the long-wavelength unit is closer to the light output side than the short-wavelength unit, the higher energy radiated by the short-wavelength light-emitting material may be absorbed by the long-wavelength light-emitting material with narrower bandgap as it travels toward the light output side; when the long-wavelength unit is further away from the light output side than the short-wavelength unit, the lower-energy radiation by the long-wavelength light-emitting material may not be absorbed by the short wavelength light-emitting material with wider bandgap as it travels toward the light output side.

The embodiments from the photonic perspective may be combined with the embodiments from the carrier perspective. For example, as described previously, when the hole transport energy level of the light-emitting material of the first unit is deeper than the hole transport energy level of the light-emitting material of the second unit, and the electron transport energy level of the light-emitting material of the first unit is not shallower than the electron transport energy level of the light-emitting material of the second unit, if the second unit is closer to either the first electrode or the second electrode which acts as the cathode compared to the first unit in the overlapping region of the first and second unit, then both the first and second unit emit light in the overlapping region, but if the cathode is configured to be on the light output side, the problem of color mixing can be alleviated or suppressed. For example, as previously described, when the electron transport energy level of the light-emitting material of the first unit is shallower than the electron transport energy level of the light-emitting material of the second unit, and the hole transport energy level of the light-emitting material of the first unit is not deeper than the hole transport energy level of the light-emitting material of the second unit, if the first unit is closer to either the first electrode and the second electrode which acts as the cathode in the overlapping region of the first unit and the second unit compared to the second unit, then the overlapping region of the first unit and the second unit will emit light, but if the anode is configured to be on the light output side, then the color mixing problem can be mitigated or suppressed.

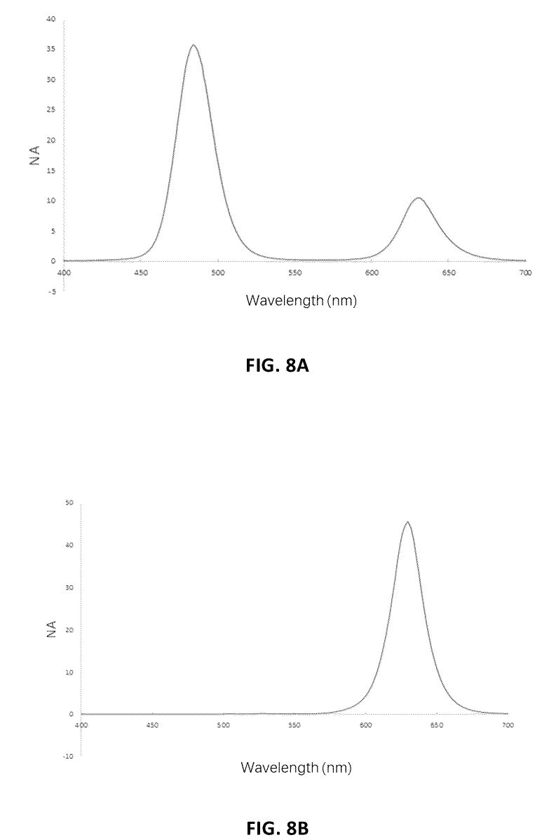

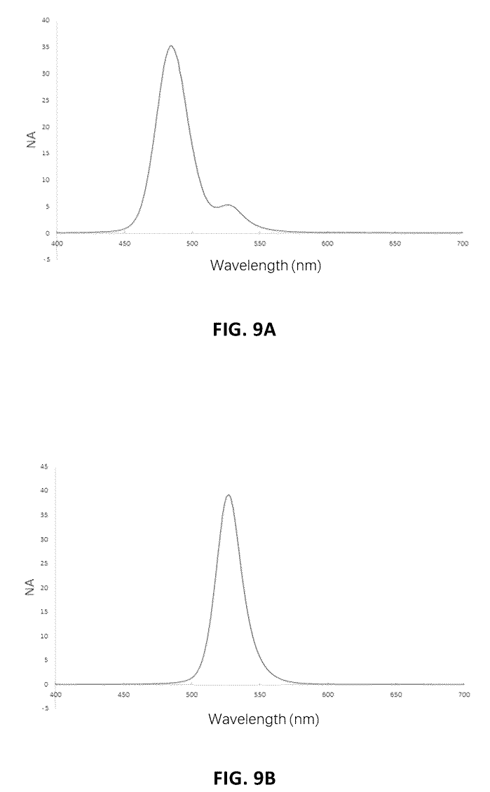

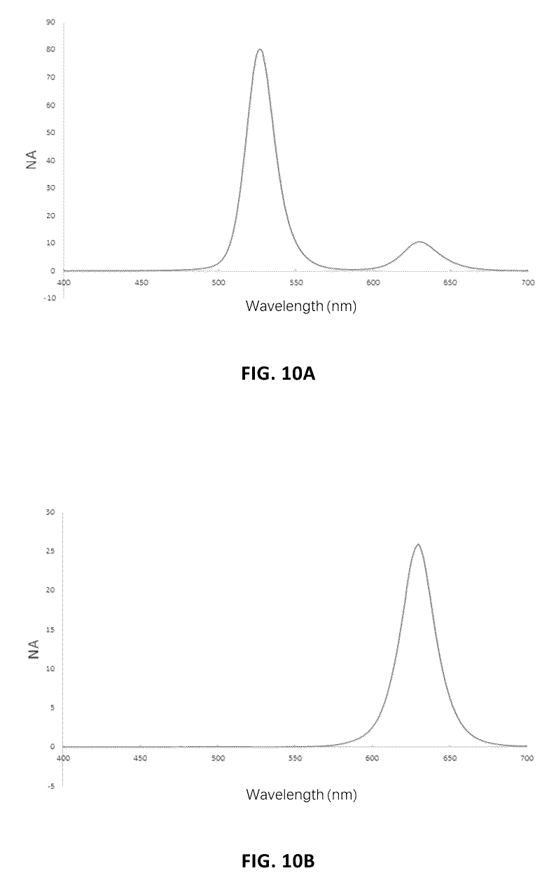

The above effects are illustrated below with specific experimental results. The inventors used the following device structure: ITO (first electrode-anode)/PEDOT: PSS (40 nm, hole injection layer)/TFB (25 nm, hole transport layer)/first quantum dot light-emitting layer QD1 (20 nm)/second quantum dot light-emitting layer QD2 (20 nm)/ZnO (40 nm, electron transport layer)/silver electrode (100 nm, second electrode-cathode). ITO serves as the light output side and the silver electrode serves as the reflective electrode. The blue QD material, the red QD material, and the green QD material selected by the inventors satisfy that the electron transport energy level of the relatively short-wavelength QD material is equal to the electron transport energy level of the relatively long-wavelength QD material, and the hole transport energy level of the relatively short-wavelength QD material is deeper than the hole transport energy level of the relatively long-wavelength QD material. The inventors measured electroluminescence (EL) spectra at an applied voltage of 5 V. The specific structure corresponding to FIG. 8A are blue QD1 and red QD2, and two EL peaks appear in FIG. 8A, located near 480 nm (blue) and near 630 nm (red). The specific structure corresponding to FIG. 8B are red QD1 and blue QD2, and only one EL peak appears in FIG. 8B, located near at 630 nm (red). The specific structure corresponding to FIG. 9A are blue QD1 and green QD2, and two EL peaks appear in FIG. 9A, located near 480 nm (blue) and near 530 nm (green). The specific structure corresponding to FIG. 9B are green QD1 and blue QD2, and only one EL peak appears in FIG. 9B, located near 530 nm (green). The specific structure corresponding to FIG. 10A are green QD1 and red QD2, and two EL peaks appear in FIG. 10A, located near 530 nm (green) and near 630 nm (red). The specific structure corresponding to FIG. 10B are red QD1 and green QD2, and only one EL peak appears in FIG. 10B, located near 630 nm (red). It can thus be seen that by reasonably setting the overlapping order of different color units in the overlapping region according to the above discussion, the electrical leakage can be inhibited, the problem of color mixing can be further suppressed.

In some embodiments, the plurality of units of the light-emitting layer includes a third unit and a fourth unit element being adjacent to each other, the third unit and the fourth unit are configured to emit light of the same wavelength range. For such embodiments, the third unit and the fourth unit may be formed integrally. For example, a pixel may typically include a red light unit R, a green light unit G, and two blue light units B1, B2, and be arranged in the order of (R, G, B1, B2), then B1 and B2 may be integrally formed but correspond to two first electrodes. In some embodiments, B1 and B2 may be integrally formed to form a large-area blue light unit B and corresponding to one first electrode, which blue light unit B may have an area that is twice the area of each of the red light unit R and the green light unit G.

Returning to FIG. 4B, in some embodiments, isolation structures extending upwardly from the substrate 201 or the first electrode 203 are not provided between the plurality of units 207 of the light-emitting layer. Alternatively, in some embodiments, as shown in FIG. 4C, the light-emitting device 200C may further include a plurality of isolation structures 213 compared to the light-emitting device 200B, which are disposed on top of the substrate 201 and extend upwardly from the substrate 201 or the first electrodes 203, with at least a portion of each of the first electrodes 203 being disposed between the corresponding isolation structures 213. In some examples, each isolation structure 213 does not extend from the substrate 201 or the first electrode 203 to a height of or above the plurality of units 207, thereby separating the plurality of units 207. In some examples, each isolation structure 213 has a height of less than 700 nm. In some examples, the height of each isolation structure 113 may be configured to be within the range of no more than the sum of the height of the stack and 200 nm and no less than the height of a functional layer directly adjacent to the first electrode in the stack directly adjacent to the isolation structure. It will be appreciated that the foregoing discussion of the light-emitting devices 100 and 100′ can all apply to the currently discussed light-emitting devices 200A through 200C and will not be repeated herein.

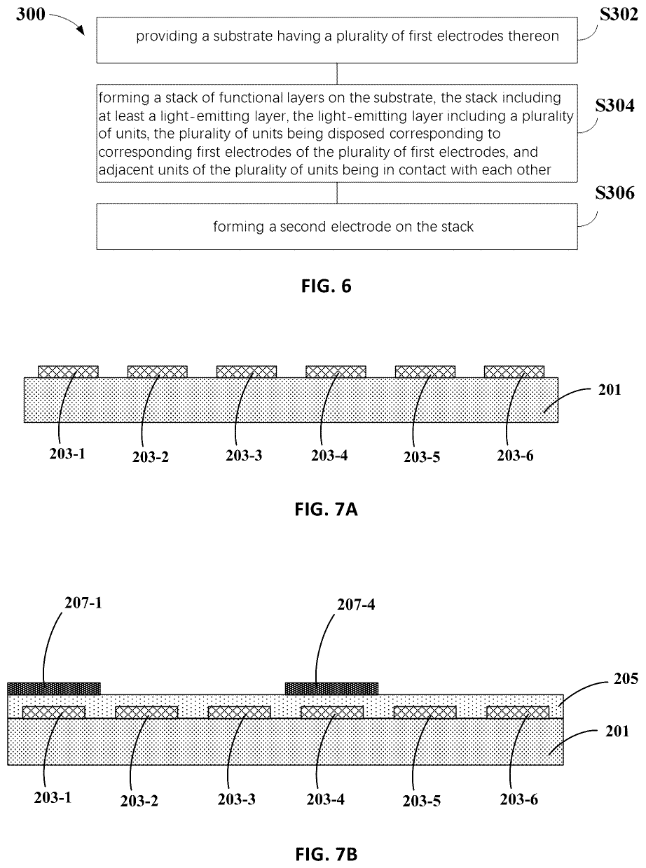

A method 300 of preparing the light-emitting device according to some embodiments of the disclosure is described below in connection with FIG. 6. The method 300 of preparing the light-emitting device may include: at step S302, providing a substrate having a plurality of first electrodes thereon; at step S314, forming a stack of functional layers on the substrate, the stack including at least a light-emitting layer, the light-emitting layer including a plurality of units, the plurality of units being disposed in correspondence with corresponding first electrodes of the plurality of first electrodes, and the adjacent units of the plurality of units being in contact with each other; at step S306, forming a second electrode on the stack.

In some embodiments, an orthographic projection of each unit on the substrate covers an orthographic projection of the first electrode corresponding to that unit on the substrate.

In some embodiments, no isolation structure is formed between the plurality of units that extends from the substrate or the first electrode up to the height of the plurality of units or above thereby separating the plurality of units. In other embodiments, a plurality of isolation structures are formed on the substrate, the plurality of isolation structures extending upwardly from the substrate or the first electrode, and at least a portion of each first electrode of the plurality of first electrodes is disposed between the corresponding isolation structures, wherein each isolation structure of the plurality of isolation structures has a height of less than 700 nm. In some examples, the height of each isolation structure is configured to be within the range of no more than the sum of the height of the stack and 200 nm and no less than the height of a functional layer directly adjacent to the first electrode in the stack directly adjacent to the isolation structure.

In some embodiments, forming the stack of functional layers at step S304 further includes forming a lower functional layer that covers the plurality of first electrodes, wherein the light-emitting layer is disposed above the lower functional layer, and wherein adjacent units of the plurality of units of the light-emitting layer are in contact with each other such that the lower functional layer is not in contact with the second electrode formed on the stack at step S306. In some embodiments, forming the stack of functional layers at step S304 further includes: forming an upper functional layer that covers the plurality of units of the light-emitting layer, wherein the light-emitting layer is disposed below the upper functional layer and wherein adjacent units of the plurality of units of the light-emitting layer are in contact with each other such that the lower functional layer does not come into contact with the upper functional layer formed on the light-emitting layer.

In some embodiments, forming the light-emitting layer at step S304 may include: in correspondence with the plurality of first electrodes, forming each liquid printing unit corresponding to the plurality of units of the light-emitting layer, the liquid printing unit containing a quantum dot composition; and crosslinking the liquid printing unit so as to form the plurality of units of the light-emitting layer.

In some embodiments, the plurality of units of the light-emitting layer includes a first unit and a second unit being adjacent to each other, the first unit and the second unit partially overlap each other. Such contact method in which adjacent units partially overlap each other may better insulate the contact between the lower functional layer and the upper functional layer than the contact method in which neighboring units are exactly adjacent (i.e., edge to edge contact). In some examples, orthographic projections of the overlapping region of the first unit and the second unit on the substrate does not overlap with orthographic projections of the first electrodes of the first unit and the second unit on the substrate. In this way, optical crosstalk of the different units can be suppressed.

In some embodiments, the first unit may be configured to emit light in a first wavelength range, and the second unit may be configured to emit light in a second wavelength range, the second wavelength range being higher than the first wavelength range. In some examples, in the overlapping region of the first unit and the second unit, the second unit is closer to either the first electrode or the second electrode which acts as the light output side compared to the first unit. In some examples, the hole transport energy level of the light-emitting material of the first unit is deeper than the hole transport energy level of the light-emitting material of the second unit, and the electron transport energy level of the light-emitting material of the first unit is not shallower than the electron transport energy level of the light-emitting material of the second unit, wherein in the overlapping region of the first unit and the second unit, the first unit is closer to either the first electrode or the second electrode which acts as a cathode compared to the second unit. In some examples, the electron transport energy level of the light-emitting material of the first unit is shallower than the electron transport energy level of the light-emitting material of the second unit, and the hole transport energy level of the light-emitting material of the first unit is not deeper than the hole transport energy level of the light-emitting material of the second unit, wherein in the overlapping region of the first unit and the second unit, the second unit is closer to the either the first electrode or the second electrode that acts as the cathode compared to the first unit. In some examples, the electron transport energy level of the light-emitting material of the first unit is shallower than the electron transport energy level of the light-emitting material of the second unit, and the hole transport energy level of the light-emitting material of the first unit is deeper than the hole transport energy level of the light-emitting material of the second unit, wherein in the overlapping region of the first unit and the second unit, the second unit is closer to either the first electrode or the second electrode which act as the cathode compared to the first unit, or the first unit is closer to either the first electrode or the second electrode which acts as the cathode compared to the second unit. For these examples, referring to the either the first unit or the second unit which is arranged to be closer to the anode as the anode-side unit, and referring to either the first unit or the second unit which is arranged to be closer to the cathode as the cathode-side unit, the forming of the first unit and the second unit may then include: forming the anode-side unit; and forming the cathode-side unit partially overlapping with the anode-side unit. For example, forming the first unit and the second unit containing the quantum dot composition may include: forming a first liquid printing unit corresponding to the anode side unit, and crosslinking the first liquid printing unit so as to form the anode-side unit; and forming a second liquid printing unit corresponding to the cathode-side unit partially overlapping the anode-side unit, and crosslinking the second liquid printing unit so as to form the cathode-side unit. Furthermore, based on the above discussion, the inventors of the present application have found that, since the reasonable setting of the overlapping order of the different color units in the overlapping region can suppress or even eliminate the color mixing problem. By determining the overlapping order in accordance with the discussion of the disclosure, different formation order can be obtained accordingly, and with such formation order, even if the extent of overlapping of the different color units is so large due to deviation in printing position and cause them to overlap each other even in each other's electrode region, there is no problem of color mixing or the problem of color mixing is not serious. Therefore, the disclosure has a high tolerance for the orienting accuracy of the ink jet printing head.

In some embodiments, the plurality of units of the light-emitting layer include a third unit and a fourth unit being adjacent to each other, the third and fourth units being configured to emit light of the same wavelength range, wherein the third and fourth units are formed integrally. In some examples, forming the light-emitting layer at step S304 may include: forming liquid printing units corresponding to the third unit and the fourth unit, an orthographic projection of the liquid printing units on the substrate both covering an orthographic projection of the first electrode on the substrate corresponding to the third unit and the fourth unit, respectively; and crosslinking the liquid printing units to form the third unit and the fourth unit.

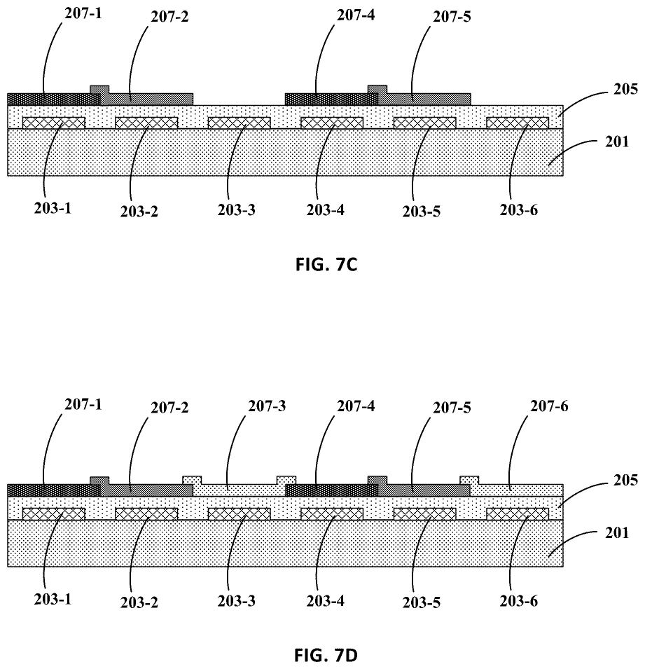

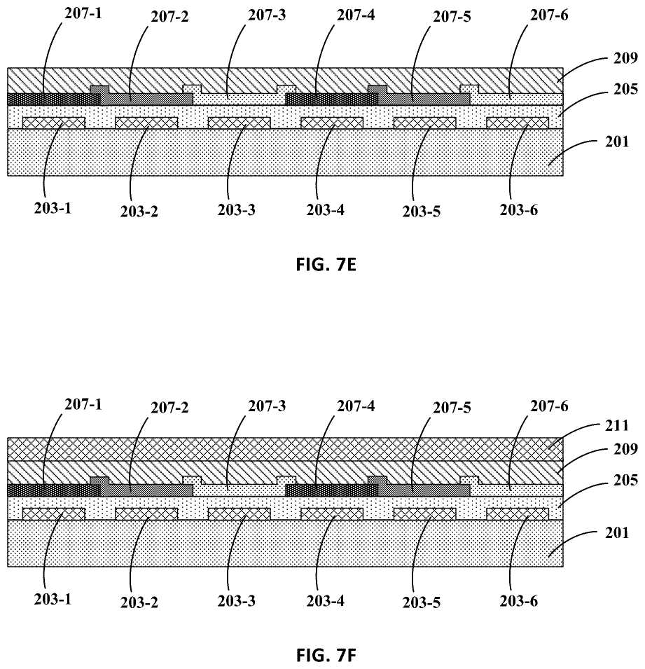

For ease of understanding, an example process for preparing R/G/B trichromatic quantum dot light-emitting device according to embodiments of the disclosure is described below specifically in connection with FIGS. 7A to 7F. The following process will be described using the first electrode as the anode and as the light output side as an example. Furthermore, although in the examples shown in FIGS. 7A to 7F, the one or more functional layers are shown in a whole sheet form, that is, the functional layers may be used together for a plurality of pixels or sub-pixels, yet in other embodiments, the functional layers may also include a plurality of units, and a single unit may be used for one or more pixels or sub-pixels.

As shown in FIG. 7A, a substrate 201 is provided having a plurality of first electrodes 203. The substrate 201 may be a TFT substrate. For example, the substrate 201 may be washed and dried sequentially using a detergent, an organic solvent, deionized water, and the like, and may additionally be subjected to a surface plasma treatment, and the like. The first electrode 203 may be, for example, ITO, but of course other suitable electrode materials may be selected according to actual needs. A plurality of first electrodes 203 may be formed by depositing an ITO film on the TFT substrate and patterning it.

It should be understood that if the foregoing design of the short isolation structure is to be applied, the substrate 201 can further be formed with a layer of isolation structure material (e.g., by chemical vapor deposition) and patterned (e.g., by photolithography) to form a plurality of isolation structures. However, in the process of FIGS. 7A through 7F, the foregoing non-isolated structure design will be illustrated as an example.

Next, the stack of functional layers may be formed. The lower functional layer 205 may be prepared on the substrate 201 formed with the first electrode 203, as shown in FIG. 7B. Although the lower functional layer 205 is illustrated as a single layer, it may include any or more layers. For example, the lower functional layer 205 may include a hole injection layer directly adjacent to the first electrode 203 and a hole transport layer disposed above the hole injection layer. For example, the hole injection layer may, for example, be PEDOT: PSS or other suitable material, and the hole transport layer may, for example, be TFB or other suitable material. They may be formed by any suitable method such as spin-coating, coating, printing or vaporizing. In some implementations, the hole injection layer can be prepared as follows: the hole injection material is formulated into an ink suitable for coating, suitable coating parameters are selected, the coating is performed, and after the coating, the substrate is placed on a hot plate and dried. Afterwards, the hole transport layer can be prepared as follows: the hole transport layer material is formulated into a printable formulation, and printed on top of the above-described hole injection layer material; the substrate is then transferred to a vacuum hot plate for drying. It should be understood that the method described herein for preparing the lower functional layer is exemplary and not limiting, those of skill in the art will appreciate that a wide variety of methods may be employed to prepare the functional layer. In some implementations, the thickness of the hole injection layer may be in the range of tens to hundreds of nanometers, such as 20-300 nm, preferably 30-150 nm, and the thickness of the hole transport layer may be in the range of tens to hundreds of nanometers, such as 10-200 nm, preferably 15-100 nm.

After the lower functional layer is prepared, a light-emitting layer can be formed on the lower functional layer. In some implementations, the quantum dot (QD) light-emitting layer can be prepared as follows: the QD stock solution is precipitated by centrifugation and then re-dispersed into a printing solvent formulation to formulate a printable ink, which is loaded into a printing device; according to the setup of the printing parameters, the QD ink is accurately printed on mutually independent electrode regions of the substrate, and the region of the corresponding first electrode is completely covered; after which the substrate is transferred to a vacuum hat plate for drying, In some implementations, the thickness of the QD light-emitting layer may be in the range of tens to hundreds of nanometers, such as 10-100 nm, preferably 15-50 nm.

In addition, the wavelength ranges of red light, green light, and blue light are sequentially lowered, as described previously. The selected red QD material, green QD material, and blue QD material have equal electron transport energy levels, and the hole transport energy levels become deeper in turn. Therefore, when the first electrode 203 is an anode, the formation order of units of the QD light-emitting layer is the red light unit, the green light unit, and the blue light unit preferably. Accordingly, as shown in FIG. 7B, red QD ink containing red QD material may be printed in an area above the lower functional layer 205 corresponding to the first electrodes 203-1,203-4, and the red QD layer is cured by thermal crosslinking after drying to form the red light units 207-1, 207-4. Then, as shown in FIG. 7C, green light units containing green QD material may be printed above the lower functional layer 205 corresponding to the first electrodes 203-2, 203-5 in a manner partially overlapping with the red light units to print green QD ink containing green QD material, and after drying, curing the green QD layer by thermal cross-linking, thereby forming the green light unit 207-1 partially overlapping with the red light unit 207-2, and the green light unit 207-5 partially overlapping with the red light unit 207-4. Finally, as shown in FIG. 7D, the region above the lower functional layer 205 corresponding to the first electrodes 203-3, 203-6 is printed with blue QD ink containing blue QD material in a manner partially overlapping with the red light unit and the green light unit, respectively, and the blue QD layer is cured by thermal crosslinking after drying to form the blue light unit 207-3 partially overlapping with the green light unit 207-3 and the red light unit 207-4 and the blue light unit 207-6 partially overlapping with the green light unit 207-3 and another red light unit not shown. The crosslinking ligand for t the quantum dots may for example be 4-[2-(2-methylprop-2-enoyloxy) ethoxy]-4-oxobutanoic acid or other suitable material, and the thermal crosslinking process may for example be a heating process for 5 minutes at 100° C.

Of course, in addition to the above-described method of printing combined with thermal crosslinking, other methods can be used to prepare the QD layer. For example, coating combined with photo crosslinking method may be used to prepare the QD layer. Specifically, a red QD material can be coated on top of the lower functional layer 205 to form a single-layer red QD film, and then a photoresist can be coated on the red QD film and a mask can be used for exposure and development to expose the quantum dot regions to be crosslinked, and then UV light through the mask can be used to irradiate the red QDs in the regions not protected by the photoresist to enable crosslinking, and then the substrate can be rinsed with a solvent of tetramethylammonium hydroxide (TMAH) to remove excess crosslinking solution and the photoresist can be removed, and finally the uncrosslinked red QDs can be removed with a solvent such as toluene, octane, or the like, then the red light units 207-1, 207-4 are formed. Next, the above steps are repeated to form the green light units and the blue light units in turn.

Next, an upper functional layer 209 may be formed on top of the light-emitting layer, as shown in FIG. 7E. While the upper functional layer 209 is illustrated as a single layer, it may include one or more layers. For example, the upper functional layer 209 may include an electron transport layer, which may be formed, for example, from ZnO or any other suitable material. The thickness of the electron transport layer may be in the range of tens to hundreds of nanometers, such as 14-400 nm, preferably 20-100 nm.

Next, second electrode 211 may be formed on top of the upper functional layer 209, as shown in FIG. 7F. In this example, the second electrode may be formed by vaporizing aluminum or silver. In some embodiments, the second electrode 211 may be configured to be formed in whole sheet to cover an area of one or more pixels (or sub-pixels). The material and formation method of the second electrode may be selected based on the actual situation. Optionally, a capping layer capable of transmitting light may be formed on the second electrode 211. Optionally, the additional substrate may also be provided on the top of the light-emitting device opposite the substrate 201 and encapsulated.

It will be understood that when the second electrode is used as the light output side, the above process of preparing the light-emitting layer may be modified to form the blue light unit first, then the green light unit, and finally the red light unit.

According to yet another aspect of the disclosure, there is also provided an electronic device which may include a light-emitting device as described in any of the embodiments or implementations of the disclosure.

The words “left”, “right”, “front”, “back”, “bottom”, “top”, “bottom”, “high”, “low”, etc., if they exist, are used for descriptive purposes and not necessarily for describing invariable relative positions. It should be understood that the words so used are interchangeable where appropriate, enabling the embodiments of the disclosure described herein, for example, to operate in other orientations than those shown or otherwise described herein. For example, when the device in the accompanying drawings is inverted, features originally described as being “above” other features may be described as being “below” other features. The device may also be oriented in other ways (rotated 90 degrees or in some other orientation), at which point the relative spatial relationship will be interpreted accordingly.

In the specification and claims, an element is the to be “over”, “attached to”, “connected to”, or “coupled to” another element, etc., the element may be directly above the other element, directly attached to the other element, directly connected to the other element, directly coupled to the other element, or there can be one or more intermediate elements. By contrast, an element is to be “directly” above another element, “directly attached to” another element, “directly connected to” another element, “directly coupled to” another element, there will be no intermediate element. In the specification and the claims, a feature arranged to be “adjacent” or “neighboring” to another feature may mean that the feature has a portion that overlaps the adjacent feature or is located above or below the adjacent feature.

As used herein, the term “exemplary” means “used as a model, example or illustration”, and not as a “model” that will be precisely reproduced. Any of the exemplary embodiments described herein are not necessarily to be construed as preferred or advantageous over other embodiments. Furthermore, the disclosure is not limited by any expressed or implied theories given in the art, the background art, the content of the invention, or the specific embodiments.

As used herein, the term “substantially” is intended to encompass any small variation due to design or manufacturing defects, tolerances of the device or component, environmental influences, and/or other factors. The term “substantially” also allows for variations from the perfect or ideal situation due to parasitic effects, noise, and other practical considerations that may be present in the actual realization.

In addition, the terms “first”, “second” and the like may be used herein for reference purposes only and are thus not intended to be limiting. For example, the terms “first”, “second” and other such numerical terms relating to structures or components do not imply order or sequence unless the content clearly indicates otherwise.

It should also be understood that the term “including/containing”, as used herein, indicates the presence of the indicated features, integrals, steps, operations, units and/or components, but does not preclude the presence or addition of one or more other features, integrals, steps, operations, units and/or components, and/or combinations thereof.

In the disclosure, the term “providing” is used in a broad sense to cover all ways of obtaining an object, so that “providing an object” includes, but is not limited to, “purchasing”, “preparing/manufacturing”, “arranging/setting up”, “installing/assembling”, and/or “ordering” an object, among others.

As used herein, the term “and/or” includes any and all combinations of one or more of the listed items in association.

The terms used herein are for the purpose of describing particular embodiments only and are not intended to limit the disclosure. As used herein, the singular forms “one”, “a” and “the” are also intended to include the plural form unless the context clearly indicates otherwise.

Those skilled in the art should realize that the boundaries between the above operations are merely illustrative. The multiple operations may be combined into a single operation, the single operation may be distributed among additional operations, and the operations may be performed at least partially overlapping in time. Moreover, alterative embodiments may include multiple instances of a particular operation, and the order of operations may be altered in various other embodiments. However, other modifications, variations and substitutions are equally possible. Aspects or elements of all embodiments disclosed above may be combined in any manner and/or in combination with aspects or elements of other embodiments to provide a plurality of additional embodiments. Accordingly, this specification and the accompanying drawings should be viewed as illustrative and not limiting.

Although some particular embodiments of the disclosure have been described in detail by way of examples, it should be understood by those skilled in the art that the above examples are for illustrative purposes only and are not intended to limit the scope of the disclosure. The embodiments disclosed herein may be combined in any combination without departing from the spirit and scope of the disclosure. It should also be understood by those skilled in the art that multiple modifications can be made to the embodiments without departing from the scope and spirit of the disclosure. The scope of the disclosure is limited by the appended claims.

What is claimed is:

1. A light-emitting device comprising: a substrate; a plurality of first electrodes disposed above the substrate; a stack of functional layers disposed above the plurality of first electrodes, the stack comprising at least a light-emitting layer, the light-emitting layer comprising a plurality of units, the plurality of units being disposed in correspondence with corresponding first electrodes of the plurality of first electrodes, and adjacent units of the plurality of units being in contact with each other; and a second electrode, disposed above the stack.

2. The light-emitting device according to claim 1, wherein, an orthographic projection of each of the plurality of units on the substrate covers an orthographic projection of the first electrode of the plurality of first electrodes corresponding to the unit on the substrate.

3. The light-emitting device according to claim 1, wherein, the stack further comprises a lower functional layer disposed below the light-emitting layer, the lower functional layer covering the plurality of first electrodes, and wherein the adjacent units of the plurality of units are in contact with each other such that the lower functional layer is not in contact with the second electrode.

4. The light-emitting device according to claim 3, wherein, the stack further comprises an upper functional layer disposed above the light-emitting layer, the upper functional layer covering the plurality of units of the light-emitting layer, and wherein the adjacent units of the plurality of units are in contact with each other such that the upper functional layer is not in contact with the lower functional layer.

5. The light-emitting device according to claim 1, wherein, the plurality of units comprise a first unit and a second unit, the first unit and the second unit being adjacent and partially overlapping each other.

6. The light-emitting device according to claim 5, wherein, an orthographic projection of an overlapping region of the first unit and the second unit on the substrate does not overlap orthographic projections of the first electrodes of the first unit and the second unit on the substrate.

7. The light-emitting device according to claim 5, wherein, the first unit is configured to emit light in a first wavelength range and the second unit is configured to emit light in a second wavelength range, the second wavelength range being higher than the first wavelength range.

8. The light-emitting device according to claim 7, wherein, in the overlapping region of the first unit and the second unit, the second unit is closer to either the first electrode or the second electrode which acts as the light output side compared to the first unit.

9. The light-emitting device according to claim 7, wherein, a hole transport energy level of the light-emitting material of the first unit is deeper than a hole transport energy level of the light-emitting material of the second unit, and an electron transport energy level of the light-emitting material of the first unit is not shallower than an electron transport energy level of the light-emitting material of the second unit, wherein, in the overlapping region of the first unit and the second unit, the first unit is closer to either the first electrode or the second electrode which acts as a cathode compared to the second unit.

10. The light-emitting device according to claim 7, wherein, an electron transport energy level of the light-emitting material of the first unit is shallower than an electron transport energy level of the light-emitting material of the second unit, and a hole transport energy level of the light-emitting material of the first unit is not deeper than a hole transport energy level of the light-emitting material of the second unit, wherein, in the overlapping region of the first unit and the second unit, the second unit is closer to either the first electrode or the second electrode which acts as a cathode compared to the first unit.

11. The light-emitting device according to claim 7, wherein, an electron transport energy level of the light-emitting material of the first unit is shallower than an electron transport energy level of the light-emitting material of the second unit, and a hole transport energy level of the light-emitting material of the first unit is deeper than a hole transport energy level of the light-emitting material of the second unit, wherein, in the overlapping region of the first and the second unit, the second unit is closer to either the first electrode or the second electrode which acts as a cathode compared to the first unit, or the first unit is closer to either the first electrode or the second electrode which acts as a cathode compared to the second unit.

12. The light-emitting device according to claim 1, wherein, the plurality of units comprise a third unit and a fourth unit that are adjacent to each other, the third unit and the fourth unit being configured to emit light of the same wavelength range, wherein the third unit and the fourth unit are integrally formed.

13. The light-emitting device according to claim 1, wherein, the plurality of units of the light-emitting layer are formed by crosslinking of a printed or coated quantum dot composition.

14. The light-emitting device according to claim 1, wherein, no isolation structure is provided between the plurality of units that extends from the substrate or the first electrode to a height of or above the plurality of units thereby separating the plurality of units.

15. The light-emitting device according to claim 1, the light-emitting device further comprising: a plurality of isolation structures on the substrate that extend upwards from either the substrate or the first electrode, at least a portion of each first electrode of the plurality of first electrodes being provided between corresponding isolation structures, wherein each isolation structure of the plurality of isolation structures has a height of less than 700 nm.

16. The light-emitting device according to claim 15, wherein, the height of each isolation structure of the plurality of isolation structures is configured to be within a range that is no higher than the sum of the height of the stack and 200 nm, and no lower than the height of the functional layer directly adjacent to the first electrode in the stack directly adjacent to the isolation structure.

17. A method of preparing a light-emitting device comprising: providing a substrate having a plurality of first electrodes thereon; forming a stack of functional layers on the substrate, the stack comprising at least a light-emitting layer, the light-emitting layer comprising a plurality of units, the plurality of units being disposed in correspondence with corresponding first electrodes of the plurality of first electrodes, and adjacent units of the plurality of units are in contact with each other; and forming a second electrode on the stack.

18. The method of preparing a light-emitting device according to claim 17, wherein, an orthographic projection of each of the plurality of units on the substrate covers orthographic projections of the first electrode of the plurality of first electrodes corresponding to the unit on the substrate.

19. (canceled)

20. (canceled)

21. (canceled)

22. (canceled)

23. (canceled)

24. (canceled)

25. (canceled)

26. (canceled)

27. (canceled)

28. (canceled)

29. The method of preparing a light-emitting device according to claim 17, wherein, the plurality of units comprise a third unit and a fourth unit that are adjacent to each other, the third unit and the fourth unit being configured to emit light of the same wavelength range, wherein the third unit and the fourth unit are integrally formed.

30. An electronic device comprising the light-emitting device according to anyone of the claim 1.
